(19) United States
(12) Patent Application Publication
(10) Pub. No.: US 2010/0154876 A1
(43) Pub. Date: Jun. 24, 2010

(54) MODULAR INTERDIGITATED BACK CONTACT PHOTOVOLTAIC CELL STRUCTURE ON OPAQUE SUBSTRATE AND FABRICATION PROCESS

(75) Inventors: Cateno Marco Camalleri, Catania (IT); Simona Lorenti, Catania (IT); Fabrizio Mangano, Catania (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (IT)

(21) Appl. No.: 12/641,634

(22) Filed: Dec. 18, 2009

(30) Foreign Application Priority Data
Dec. 19, 2008 (IT) VA2008A000067

(51) Int. Cl. H01L 31/04; H01L 31/00; H01L 31/18

(52) U.S. Cl. 136/255; 136/261; 438/97; 438/96; 257/E31.003; 257/E31.04

(57) ABSTRACT

A back contact integrated photovoltaic cell includes a substrate having a dielectric surface and a patterned metal layer with parallel spaced alternately positive and negative electrode fingers forming an interdigitated two-terminal structure over the dielectric surface of the substrate. A dielectric filler may be in the interstices of separation between adjacent spaced parts of the patterned metal layer. Parallel spaced strips, alternately of p⁺ doped polysilicon and of n⁺ doped polysilicon, may top the positive and negative interdigitated electrode fingers, respectively, and form doped p-type active regions and n-type active regions of the integrated photovoltaic cell, spaced and isolated by a strip of undoped or negligibly doped polysilicon. An n⁻ or p⁻ doped or intrinsic semiconducting layer of at least partly crystallized silicon, forming a semiconductor region of thickness adapted to maximize absorption of photonic energy when illuminated by sunlight, may cover the interdigitated active doped regions.

### FILED OF THE INVENTION

The present disclosure relates, in general, to thin film photovoltaic cells for converting solar radiation (solar cells) formed at the surface of a substrate and, in particular, to back contacted vertical cells and related fabrication processes.

### BACKGROUND OF THE INVENTION

Solar cells are conversion devices of solar radiation to electrical energy. In general, the cells are made by forming P-type regions and N-type regions in a semiconductor material (photodiodes). The solar radiation, by illuminating the cell, generates electron/vacancy pairs that migrate respectively towards the P-type region and the N-type region, creating a voltage difference at the diode terminals.

In a back contacted solar cell, both N-type doped and P-type doped regions, commonly interdigitated between each other, as well as the current collecting electrodes respectively connected to them that may also form the connecting terminals of a cell to an electric load using the generated energy, are all defined at the back of a semiconductor wafer. The wafer is normally as thin as possible to minimize the required amount of expensive semiconducting material (typically silicon).

An advantage of back contacted solar cells is the absence of opaque conducting metal structures and/or of significantly opaque diffusions at the front of the wafer, though the surface of which enters the solar radiation.

There are many types of solar cells. An important technological divide is that among solar cells defined on a wafer of semiconductor material (commonly of polycrystalline or monocrystalline silicon), and so called thin film solar cells. Thin film solar cells may be formed over a purely mechanical supporting substrate through deposition, patterning and/or phase segregation/transformation, doping and other treatments of conducting, dielectric and semiconducting films. Thin film solar cells commonly have a thickness on the order of nanometers up to few thousands of nanometers.

The particularly advantageous aspects of thin film cells is a dramatic reduction of the quantity of valuable materials, in particular of semiconductors, that are used, compared to solar cells formed on classical monocrystalline or polycrystalline semiconductor substrates. These substrates by far represent the most relevant cost element, also given the rather low yield per unit area of common solar panels (that is of photovoltaic conversion devices not of concentration type).

In any case, an important efficiency parameter is the ratio between active area and total area of the panel tied to the opaque footprint of a current collecting metal grid that may be present on the front (illuminated surface) of the panel. The total area includes an area, also unavailable for conversion, dedicated to the formation of isolations among adjacent cells and interconnections the numerous cells or multicellular wafers arranged over a relatively ample surface of a panel, according to a certain series-parallel scheme as electrical connection.

In order to reduce the amount of unused area, instead of connecting the unit cells among each other according to a design series-parallel scheme of the multicellular panel already during monolithic integration of the cells on the substrate, a post-isolation and/or post-connection of the unit cells may be performed by laser scribing. Laser scribing may even be done through the same substrate if it is of a transparent material or through the wafer front or stack of thin layers deposited and processed onto the substrate surface. However, the laser scribing technique of localized fusion may augment crystal lattice defectivity which, though localized, may sensibly penalize conversion efficiency, by causing more or less diffused short circuits among distinct electrical structures of the integrated photodiode.

In general, there is the aim of optimizing the architecture of integrated photovoltaic structures by striking the best compromise between sensibly incrementing the unused area by realizing electrodic structures of high contact density for minimizing intrinsic (parasitic) resistance of the single cells, or admitting a higher intrinsic resistance and favoring a reduction of the unused area.

As already mentioned, the architectures of photovoltaic cells in which both structures for electrical contact and termination of each cell (that in the present context are also intended as cell module or generally any elementary module replicable over the extended surface of the panel) are formed at the back of the cell offer decisive advantages in enhancing area exploitation.

On the other end, efficiency and fabrication costs remain fundamental marketing parameters of a solar panel in an extremely competitive commercial context among different renewable and non renewable energy sources, therefore solar cell structures of enhanced yield and reduced costs of fabrication are constantly the object of developments and technological advances.

### SUMMARY OF THE INVENTION

An efficient back contacted solar cell structure and an effective process of fabrication that lends itself to the formation of interconnected arrays of cells according to a desired series-parallel scheme, directly over substrates of relatively large dimension, using simple and low cost techniques industrially usable for producing efficient and low cost panels of large sizes, are herein disclosed.

The present disclosure concerns a back contacted photovoltaic cell comprising an integrated diode structure of polycrystalline silicon (briefly polysilicon), or in any case of silicon, at least a partially crystalline state, processed according to a thin film technology, that may not use silicon wafer or multi micron-thick layers of silicon wafer separated from a mother wafer.

The integrated photodiode structure is defined, according to a common interdigitated architecture, by alternated P-type and N-type doped regions in the form of adjacent parallel stripes (fingers) of a polysilicon film, spaced and isolated one from the other by intervening narrow stripes of undoped polysilicon. The P-type and N-type doped regions are in electrical contact with underlying metal stripes or fingers of coincident interdigitated electrode structures of back contacting and electrical termination of the cell (integrated photodiode) defined over the surface of a mechanical substrate having at least a dielectric superficial region or surface coat.

A semiconducting silicon layer is at least partially crystalline, and of a thickness generally greater that the thickness of the underlying interdigitated stripes of doped polysilicon, such to maximize absorption therein of photonic energy, covers the interdigitated p⁺ and n⁺ regions, thereby acting as a photonic energy absorption region of the diode. This absorption region may be slightly doped with a p-type dopant or an n-type dopant, or left with its intrinsic electrical characteristics depending on the peculiarities of the integration process and of the material used.

Depending on the characteristics of the materials used, it may be useful to top the absorption layer with a thin film of at least partially crystalline silicon, doped with the same time of conductivity of that of the underlying absorption layer. This confers to the topping film of polysilicon a relatively high electrical conductivity, the function of which is to contrast recombination of mobile vacancies and electrons generated in the underlined absorption region by absorption of photonic energy.

The spacing/isolating stripes of undoped polysilicon between adjacent p⁺ and n⁺ doped regions effectively isolate laterally adjacent active regions of opposite type of conductivity, minimizing efficiency losses in the process of conversion of the photonic energy in the blanket layer of semiconducting polysilicon that acts as intrinsic semiconductor of the integrated structure of the photodiode. The photodiode may be of multijunction type and, for some peculiarities, similar to a pin or nip structure, equating the absorption layer to the intrinsic semiconductor region i or the pin or nip diodes of photovoltaic cells of amorphous silicon.

Preferably, an anti-reflecting surface film may also be present, for example a film of hydrogenated silicon nitrate, of thickness in the order of 1 or few hundreds of nanometers.

The active p⁺ and n⁺ polysilicon regions of the interdigitated anode (p⁺) and cathode (n⁺), respectively of the integrated diode structure, may be formed starting from a blanket layer of hydrogenated amorphous silicon, and by printing, for example, with serigraphic, tampographic or inkjet printing techniques, a layer of a donor material of the dopant species, for example boron for doping and crystallizing hydrogenated amorphous silicon to a p⁺ doped polysilicon, or phosphorous for doping and crystallizing hydrogenated amorphous silicon to an n⁺ doped polysilicon.

Alternatively, it is possible to apply the donor material by CVD deposition or pre-deposition, using suitable precursors such as for example: POCl₃, BCl₃, boron nitrate and the like. In this case, masking steps of the non doped regions and successive removal of the masked materials and of the residues of the deposited donor material at the end of the doping process, are helpful.

Doping of silicon by diffusing a dopant from a printed donor layer into the hydrogenated silicon accompanied by release of hydrogen, may be conducted, preliminarily in an oven, by laser beam activation, or by luminating the printed surface with non monochromatic light from flash lamps and the likes.

Alternatively, diffusion of the dopant may take place during the heat treatment that is done for transforming the deposited amorphous silicon in polycrystalline silicon, preferably under treatment conditions that favor the growth of crystal grains of large sizes (in the order of tenth of a micrometer up to several tens of micrometers).

The interdigitated back contacted integrated photodiode cell structure may be economically and easily fabricable even on large size substrates for realizing arrays of a theoretically unlimited number of cells, the electrical terminations of which may be pre-ordinately interconnected according to a certain series-parallel scheme over the surface of the substrate. The geometrical details of the integrated structure are definable with techniques applicable to substrates of large size, such as of deposition, heat treatment, laser scribing steps, printing and lithography.

These features of the present disclosures will become apparent to any person with ordinary knowledge of the specific technical field, by reading through the whole detailed description herein provided that refers to a number of drawings in order to facilitate comprehension and practice of this invention.

### BRIEF DESCRIPTION OF THE DRAWINGS

FIG. 1 is a cross sectional schematic view of an integrated interdigitated solar cell structure according to an embodiment of this invention.

FIG. 2 is a layout view of the interdigitated integrated cell structure of FIG. 1.

FIG. 3 is a layout of a photovoltaic panel comprising four integrated cells in series, according to an embodiment of this invention.

FIG. 4 is a schematic cross section showing a technique of post-connection and isolation of a number of cells in series for forming a multicellular module, according to an embodiment of this invention.

The series of FIG. 5-12 illustrates main steps of a fabrication process of the integrated cells of this invention.

### DESCRIPTION OF THE PREFERRED EMBODIMENTS

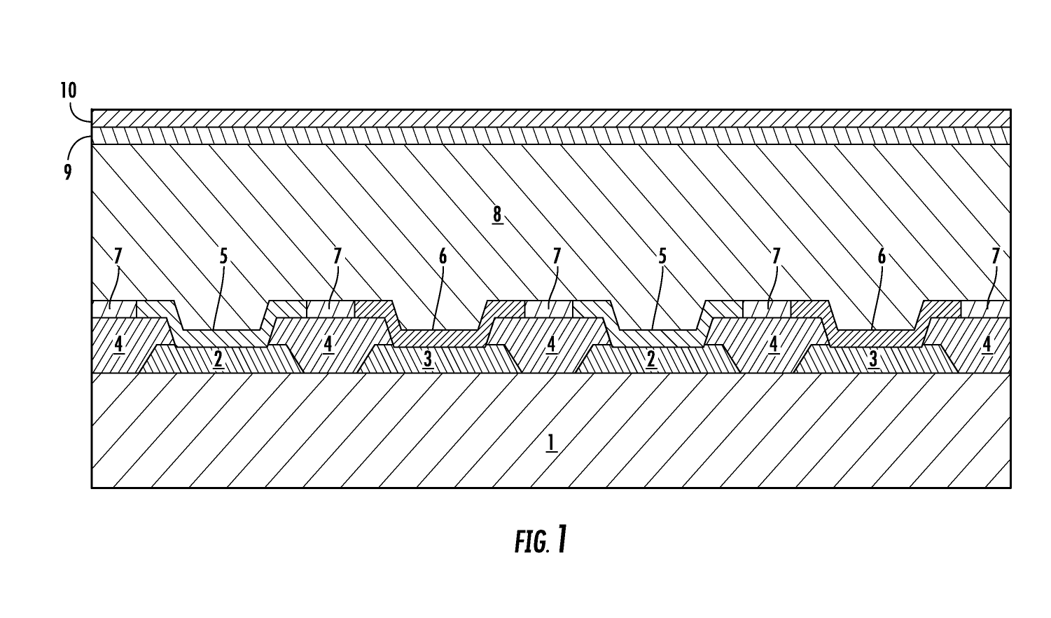

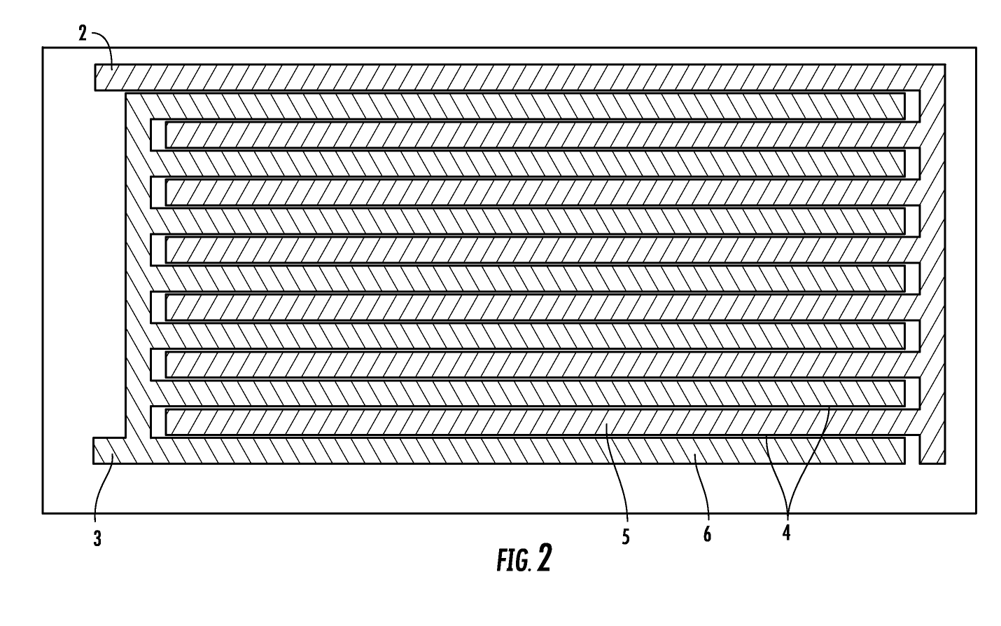

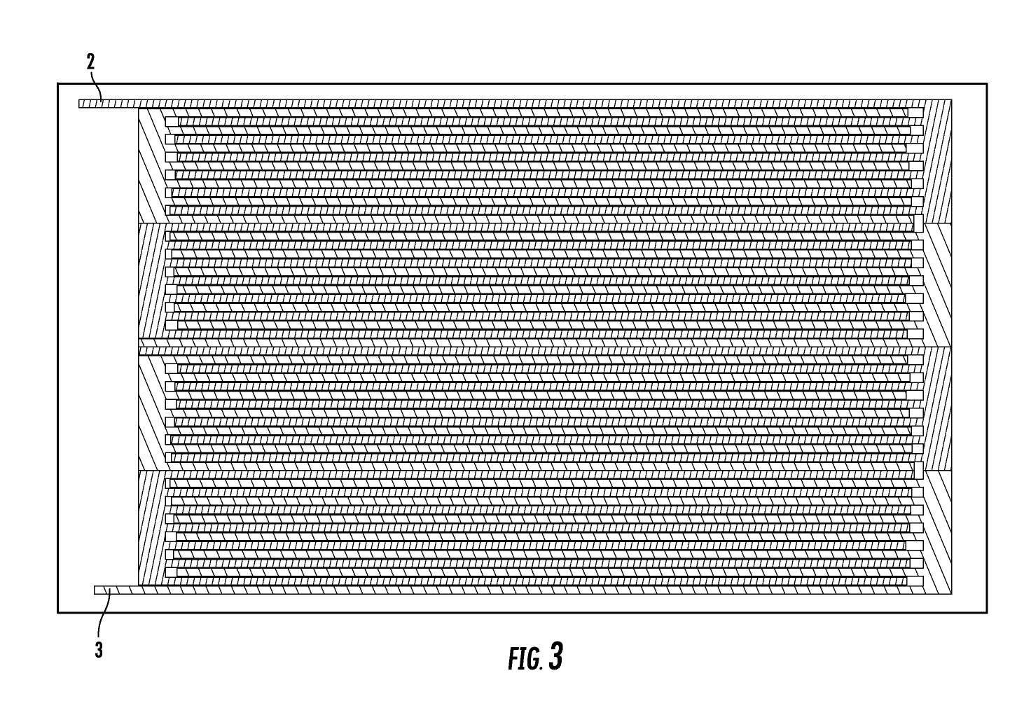

An exemplary embodiment of the novel integrated structure of a polycrystalline silicon diode, or of least partially crystalline silicon at of the photovoltaic cell, of this disclosure is shown in the partial cross sectional view of FIG. 1.

The mechanical supporting substrate 1 may be of any metallic, ceramic or glass-ceramic material suitable to withstand process temperatures, of values ranging from about 600 to about 1,000° C., and possibly up to about 1,200° C., or even higher.

Examples of suitable materials are titanium, the surface of which may be rendered electrically insulating by growing a surface oxide film, anodized aluminum (suitably limiting the maximum process temperature), sheet copper, nickel, stainless steel or hastelloy provided with a ceramic coat, ceramic or glass-ceramic plates.

Two distinct interdigitated electrode structures 2 and 3 of back contact and electrical connection of the cell may be made of the same metallic material, and may be adapted to resist the process temperature used for to the formation of the integrated diode structure, without significantly compromising characteristics of electrical conduction. An example of suitable material with these characteristics is molybdenum, which is a metal often used for making current collecting structures on large thin film solar panels based on CIS (copper-indium-selenide) or CIGS (copper-indium-gallium-selenide).

Deposition of a layer of adequate thickness, commonly between 10 and 100 or more micrometers, can be carried out by chemical phase deposition, sputtering, printing or other suitable technique.

The separation gaps between adjacent parallel metal stripes of the two interdigitated electrode structures may be filled with a dielectric material 4, typically an oxide, as for example SiO₂ or Al₂O₃, though other oxides may be used.

The dielectric 4, as shown in FIG. 1, is defined such to let it overhang above the upper edges of the metal stripes 2 and 3, such to define active areas directly on the electrode stripes 2 and 3, depressed by a depth that may be comprised between few hundreds of nanometers up to not more than 100-150 micrometers, from the crests of the isolation dielectric layer 4.

The active regions of n⁺ doped polysilicon 5 and the active regions of p⁺ doped polysilicon 6 are formed directly above the respective electrode stripes 2 and 3 and in electrical contact with the same, in a deposited mother layer of hydrogenated amorphous silicon (A-SI:H) of a thickness that may generally be comprised between ranges of about 30-50 nanometers to 150-200 nanometers. Stripes 7 over the stripes of dielectric oxide 4 of undoped polysilicon separate and electrically the adjacent stripes of doped silicon 5 and 6 isolate.

The wavy profile assumed by the deposited silicon mother layer, from which by differentiated doping and crystallization parallel active regions 5 and 6 and isolation regions 7 are formed, favors application of a relatively thick layer of donor material of the dopant species in the depressed areas by an appropriate printing technique, for example by serigraphy, tampography, or inkjet almost exclusively over the flat bottom of the depressed areas of the surface of the mother layer, by filling at least in part the depressions. In this way, separation of n⁺ and p⁺ regions of the integrated diode structure is reliably secured by the presence of separation stripes 7 of undoped polysilicon. Separation is also secured by a reduced dopant concentration in the portions of the mother layer and those immediately superimposed onto the dielectric oxide 4, which may occur in a limited measure by the diffusion of the dopant in a lateral direction relative to the thickness of the mother layer, according to a fabrication process that will be described in greater detail later on.

The blanket layer 8 of polycrystalline, or at least partially crystallized silicon, may have a conductivity of type N or P or even intrinsic. It is the photonic energy absorption region of the integrated interdigitated structure of photovoltaic cell of the present invention.

The thickness of the photonic energy absorption layer 8 is adapted to maximize absorption of solar light and generally may vary between few hundreds of nanometers up to several tens of micrometers and even surpass 100 micrometers. In general, the thickness of the absorption layer 8 should not be greater than five to ten times the diffusion length of carriers within the absorption layer. The diffusion length is a function of characteristics of the absorption region in terms of carrier mobility and lifetime of the carriers that are generated in the material. To this end, the fabrication process, as will be illustrated later, should strive to maximize these parameters through specific optimization treatments for improving the crystallographic structure of the absorption region layer 8, and/or for passivating active crystal defects that would act as centers of generation/recombination of carriers.

A superficial layer 9 of a thickness generally on the order of tens of nanometers up to few hundreds nanometers, the doping of which may be of the same type of conductivity of the underlying absorption region 8, and such to confer to the relatively thin superficial layer 9 a relatively high electrical conductivity, is preferably included in the structure. The superficial layer is included for recombination of mobile carriers (vacancy and electrons) that are generated in the underlying region 8 of lesser dopant concentration upon absorbing photonic energy. The conductive superficial layer favors migration of the majority of the generated carriers towards the respective doped regions 5 and 6 of the integrated photodiode structure.

Preferably, an optional anti-reflective film 10 may also be present, for example of silicon nitride, titanium oxide or silicon. Generally, the thickness of this anti-reflective surface film does not exceed 500 nanometers.

FIG. 2 is a layout of an integrated photovoltaic cell in which is clearly observable the interdigitation of fingers of active regions of N-type 5 and of P-type 6 and of the isolation dielectric 4 through the transparent layers 8, 9 and 10 of the structure of FIG. 1.

FIG. 3 is an exemplary layout of a module, comprising four integrated photovoltaic cells electrically connected in series, that can be reproduced innumerable times in order to cover the whole area of a solar panel of large dimensions, having a plurality of such modules electrically connected according to a certain design series-parallel scheme.

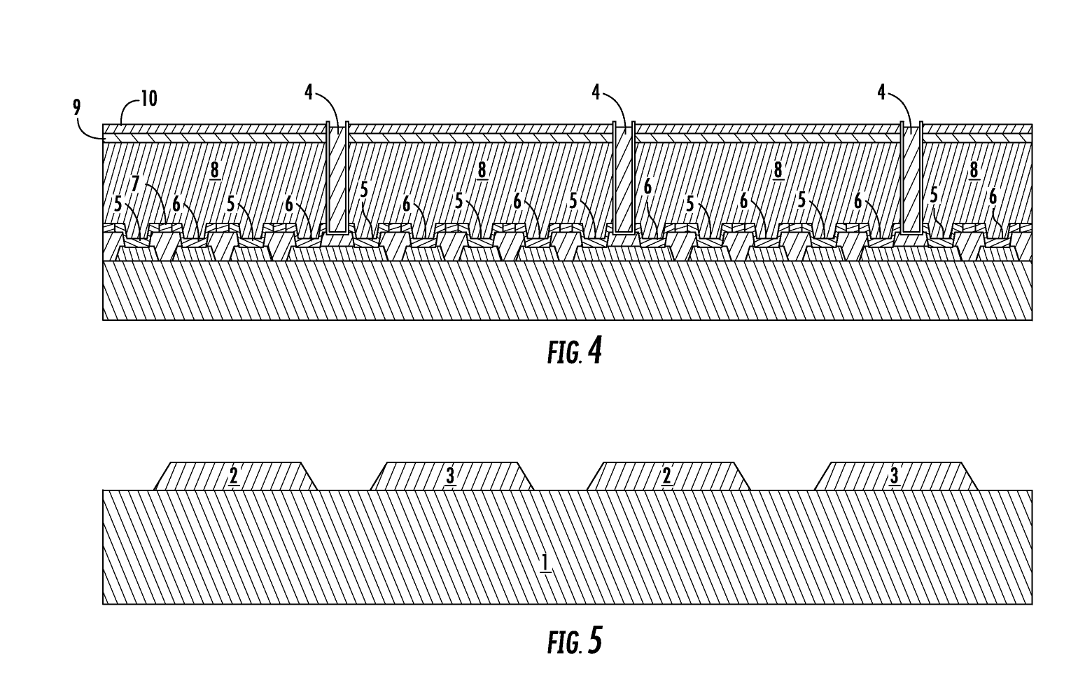

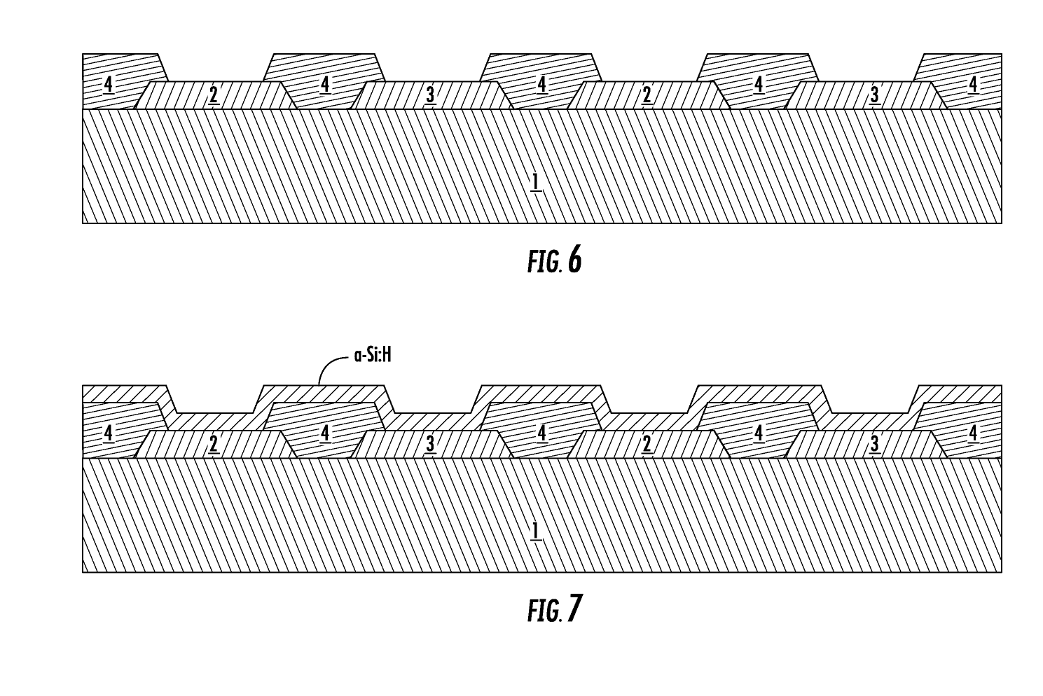

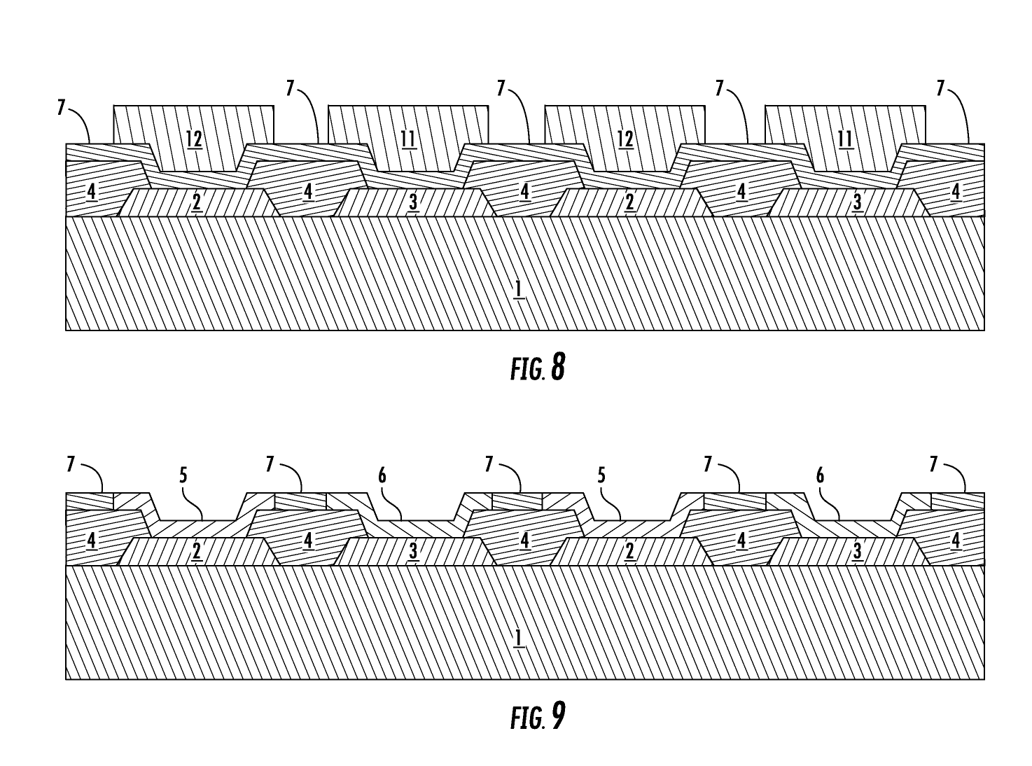

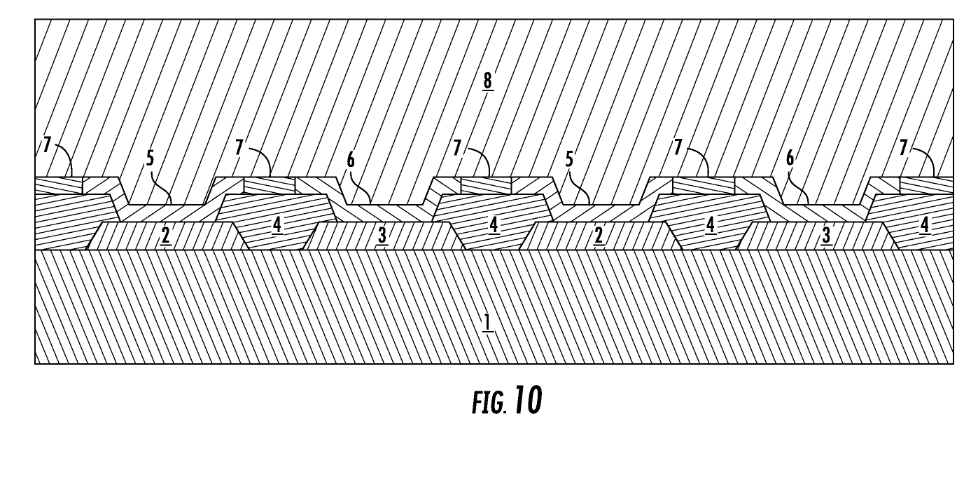

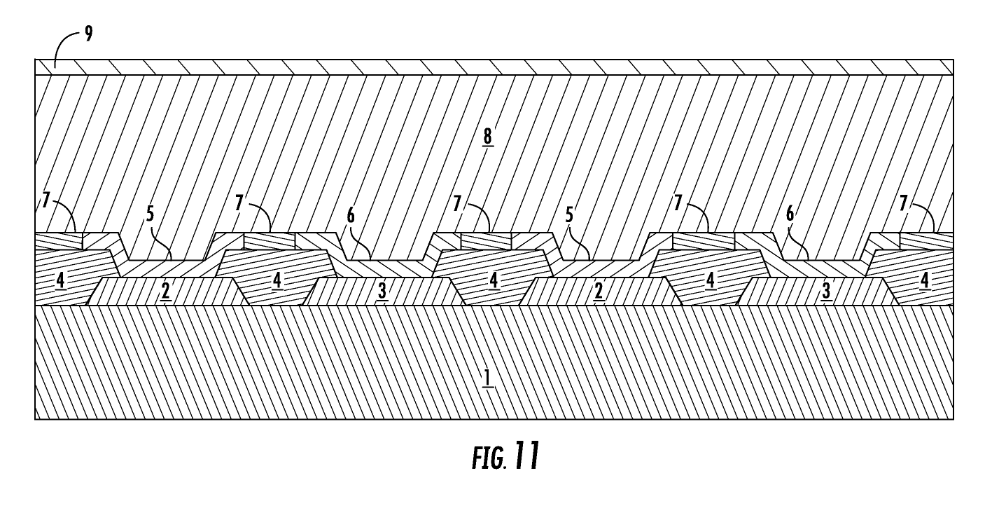

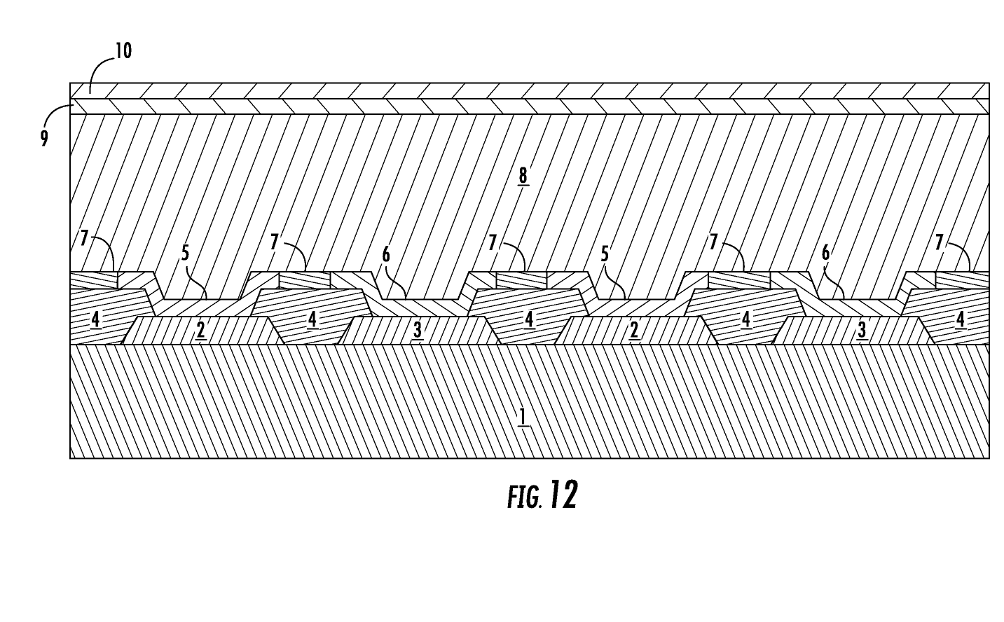

FIG. 4 shows how single cells and/or single modules part of a chain of cells or modules electrically in series may be structurally isolated and thus be connected according to a series-parallel scheme that may be pre-established during patterning of the metal layer 2-3. This is accomplished through a post isolation step of integrated cells that contemplates a deep trench cut by laser beam or through a masked plasma etch of the transparent surface layers 10, 9 and absorption region 8, forming trenches 4 that may then be filled with an appropriate dielectric.

Solely for illustrative purpose, an exemplary process of fabrication of a back contact, interdigitated thin film photovoltaic cell of the present disclosure will be described in details.

The series of figures from FIG. 5 to FIG. 12 illustrates the main and significative steps of the fabrication process, which may be conducted with techniques commonly used in the industry.

FIG. 5 shows the cross-section that is obtained upon concluding the first step of deposition on the surface (of dielectric properties) of the substrate 1, of a layer of uniform thickness of a metal. The layer is adapted to establish a good electrical contact with doped polysilicon that is defined by etching though the openings of a mask of resist, oxide, or any other suitable masking material, that can be formed or applied onto the surface by an appropriate printing technique (serigraphic, tampographic, inkjet). The parallel stripes 2 and 3 belong to two distinct interdigitated current collecting electrodes of termination of the integrated structure of the photovoltaic cell being fabricated.

FIG. 6 shows the cross-section obtained at the end of a phase, which after removal of the masking material used for defining the interdigitated electrodic structures 2 and 3, contemplates first a planarising deposition of a dielectric layer adapted to fill the interstices between adjacent metal stripes 2 and 3. The dielectric may be an oxide, an oxy-nitride, or a nitride, for example SiO₂, and deposition is continued as far as obtaining a deposited layer with a substantially planar surface. Thereafter, the dielectric is removed from active areas through a photolithographic process, with a subtractive printing technique, or by depositing in the desired areas the dielectric material by additive techniques (such as printing, deposition over shadow mask, and the like).

In case of blanket deposition of the dielectric, this second masking step can be also carried out with a printing technique (serigraphic, tampographic or inkjet) using a masking layer of resist, or of any other material capable of withstanding the etching solution of the dielectric is formed onto the planarized surface. The active areas of the integrated structure are defined directly above the respective metal electrodes 2 and 3, from where the dielectric is etched off, thus leaving isolation stripes 4 of dielectric which, to some extent, overstep the upper edges of definition of the metal stripes 2 and 3 by a height that may be comprised between few hundreds of nanometers, up to about a hundred micrometers from the plane of the metal stripes 2 and 3.

As shown in FIG. 7, after having eventually removed residue of the mask material and leached off the native oxide from the exposed surfaces of the metal stripes 2 and 3, a mother layer of silicon, preferably undoped, such as a layer of hydrogenated amorphous silicon (A-SI:H) or of partially crystalline silicon, is deposited under conditions of highly conformal deposition, over the whole surface. It is also deposited over the defined active areas in contact with the exposed surfaces of the electrode structures 2 and 3, and also over the stripes of isolation dielectric 4. Deposition of the mother layer of silicon may be carried out according to any of the commonly used techniques of conformal deposition, for example by RF-PECVD DC-PECVD VHS PECVD, Microwave-PECVD, sputtering, Photo-CVD or Hot-wire.

RF-PECVD and DC-PECVD are particularly suitable techniques for obtaining a deposited silicon layer highly conformal to the wavy prophile of the surface receiving the deposit.

The thickness of the mother layer of silicon may generally be comprised between few tenth of nanometers up to few tenth of microns, or even a little more, depending on the doping technique that is intended to be used.

After having deposited the mother layer of silicon, appropriate printing technique pastes or inks stripes 11 and 12, containing substances rich of the specific dopant species, respectively (for example boron for P-type doping or for example phosphorous for N-type doping), over the areas of regions of the mother layer of silicon that will be converted respectively to n⁺ doped polycrystalline silicon 5 and to p⁺ doped polycrystalline 6.

FIG. 8 illustrates the application of layers of paste or ink donor of either p-type dopant 11 and of n-type dopant 12, over active areas geometrically topping the metal stripes 3 and 2 of the respective electrodes. Application of the donor substances 11 and 12 may be carried out with an appropriate printing technique such as serigraphic, tampographic or inkjet. Serigraphy and tampography are printing techniques particularly suited and adapted to favor deposition of a relatively thick layer of donor substance of the drogant species over the bottom of the parallel extending depressed areas of the mother layer of hydrogenated amorphous silicon A-SI:H.

The donor substances 11 and 12, respectively printed over active areas to be formed of p-type and of n-type, and therefore adapted to make p-type dopant (for example boron) or n-type dopant (for example phosphorous) to the underlying silicon of the mother layer, may be commercial serigraphic pastes produced by the companies Ferro or by E.I. Du Pont de Nemours, chosen in function of the relative successive curing technique (heat treatment or UV).

FIG. 9 shows the cross-section of the integrated structure being fabricated after diffusion, in the silicon of the mother layer, the dopant species of p-type and of n-type from the respective donor pastes or inks printed over the alternated parallel active area projectively over the respective metal lines 3 and 2 of the distinct electrode structures, and after having removed the residues of the donor substances applied by printing from the surface of the amorphous silicon mother layer.

During the heat treatment of diffusion and activation of the dopant species of n-type in the areas 5 and of p-type in the areas 6 of the conformally deposited silicon mother layer, for example of hydrogenated amorphous silicon that during the heat treatment of diffusion releases the hydrogen contained therein, a substantial crystallization of the silicon is produced. The silicon may therefore transform into an n+ doped polysilicon in regions 5, and into a p+ doped polysilicon in regions 6, while remaining substantially undoped and practically not electrically conductive in the regions 7 above the underlying stripes 4 of dielectric material.

At treatment temperature of diffusion and activation of the dopant exceeding the transition temperature from the amorphous phase to crystalline phase of the silicon, formation of crystalline grains and/or growth of crystal dominus that may be present in the deposited silicon takes place.

During the heat treatment, the silicon if deposited in hydrogenated amorphous form releases hydrogen and a simultaneous diffusion and activation of the dopant takes place.

It is possible to employ common ovens as well as optical apparatuses monochromatic (laser) or polychromatic (flash lamps) for carrying out diffusion/activation and crystallization.

Compatibly with the overall integration process, the heat treatment of diffusion activation and crystallization may even become part of the doping step itself, by introducing in the treatment chambers suitable precursors of the dopant species. In this case, it may be helpful to form suitable masks over the deposited mother layer of silicon in order to localize distribution of the relevant donor material.

FIG. 10 shows the cross section obtained after depositing a photonic energy absorption layer 8, which in the considered exemplary embodiment, is of N-type polysilicon (slightly doped n⁻ silicon with a dopant concentration not exceeding 1×10¹⁷ atoms/cm³). N-type polysilicon may be deposited, for example, by a CVD technique in presence of phosphine or arsine, at a temperature comprised between 500 and 1100° C., for a time sufficient to obtain a layer of thickness that may in a range from about 100 nm to 100 μm, and more preferably between 300 and 500 nm, with a concentration of phosphorous not exceeding 5×10¹⁶ atoms/cm³.

In order to ensure an enhanced “continuity” between the doped polysilicon layer and the photonic energy absorption layer 8 of slightly doped polysilicon deposited thereon, the process flow may include a surface pre treatment of the doped polysilicon layer before depositing thereon the polysilicon of the photonic absorption layer 8, in order to reduce the presence of native oxides or other native compounds on the surface receiving the deposition. Native compounds are present at the surface of the doped polysilicon layer because of exposition to ambient atmosphere, whether of a storage ambient as well as of the processing atmosphere during the preceding heat treatment steps. Such a surface pre-treatment may be a wet treatment using, for example, a HF solution or in gaseous atmosphere, for example in hydrogen plasma or in presence of molecular or radical hydrogen at high temperature or in vapors of anhidrous HF).

A photonic absorption layer 8 of partially crystalline silicon that is also partially amorphous may have mobility and/or lifetime values of electrical carriers not entirely satisfactory because of lattice defects existing within crystal grains as well as at boundaries between adjacent crystal grains.

In order to reduce the effects of these defects, it may be useful to hydrogenate the deposited silicon layer. In practice, the photovoltaic device been manufactured may be exposed to atmospheres saturated with hydrogen, preferably non-molecular hydrogen, and energy may be applied for diffusing hydrogen or a precursor thereof in the polycrystalline lattice of the deposited silicon layer, such to promote passivation of defects by bonding thereto hydrogen or a hydrogen precursor.

Various treatment schemes of the many known in the silicon processing art may be followed, such as diffusion of hydrogen from a hydrogenated layer deposited over the surface of the silicon (for example a deposited silicon nitride layer as it may be already contemplated for forming an anti-reflective surface film) with a PECVD technique and therefore rich in hydrogen may be exploited as an effective hydrogen donor, or by exposing the article been manufactured to a plasma of hydrogen or of a hydrogen precursor compound. This step may be introduced in the process flow where appropriate, such as after having carried out crystallization of the silicon of the photonic absorption layer 8, taking into account the shielding characteristics to hydrogen diffusion that may have more strongly doped surface layers (9), e.g. the diffused layer surface that may be included according to a preferred embodiment of the invention, as disclosed in more detail herein below.

As shown in FIG. 11, over the photonic absorption layer 8 of n⁻ polysilicon, an n⁺ shallow junction diffusion 9 may be formed, of thickness generally not exceeding 200 nm. The junction region 9 is preferably formed by diffusing dopant of the same type of conductivity of the dopant of the absorption region 8 by exposing the surface of the deposited silicon layer to a POCl₃ atmosphere.

The integrated structure thus fabricated may also be further treated at a temperature comprised between 600 and 1000° C., in order to recrystallize the surface junction n−/n+ to which may follow an annealing treatment at a temperature of 900° C. for a period comprised between about 30′ and 3 hours.

Finally, as shown in the cross-section of FIG. 12, on the front of the device, an anti-reflective film 10 may be deposited, for example a film of silicon nitride of thickness generally not greater than 500 nm, subjected to a hydrogenation treatment according to any of the common techniques used in the field for this purpose.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1-10. (canceled)

11. A photovoltaic cell comprising:
a substrate;
positive and negative interdigitated electrode fingers adjacent the substrate;
spaced p-type and n-type semiconductor strips on the respective positive and negative interdigitated electrode fingers;
a respective undoped semiconductor strip between adjacent p-type and n-type semiconductor strips; and
a semiconductor layer covering the spaced p-type and n-type semiconductor strips and the undoped semiconductor strips.

12. The photovoltaic cell of claim 11, wherein the substrate comprises a dielectric surface.

13. The photovoltaic cell of claim 11, further comprising a dielectric filler between adjacent ones of the interdigitated electrode fingers.

14. The photovoltaic cell of claim 11, wherein the p-type and n-type semiconductor strips comprise p-type and n-type polysilicon respectively, and wherein the semiconductor layer comprises at least partly crystallized silicon.

15. The photovoltaic cell of claim 11, wherein the positive and negative interdigitated electrode fingers comprise metal.

16. The photovoltaic cell of claim 11, further comprising a topping layer on the semiconductor layer comprising at least partly crystallized semiconductor having a same conductivity type and a greater dopant concentration than the semiconductor layer.

17. The photovoltaic cell of claim 16, wherein the topping layer has electrical characteristics for recombination of mobile carriers produced by absorption of photonic energy in the semiconductor layer.

18. The photovoltaic cell of claim 11, wherein the semiconductor layer has a thickness of between 30 nm and 200 nm.

19. The photovoltaic cell of claim 11, wherein the semiconductor layer has a thickness of between 200 nm and 100 μm; and wherein and the topping layer has a thickness of between 50 nm and 200 nm.

20. The photovoltaic cell of claim 11, wherein the topping layer is one of p⁺ and n⁺ doped.

21. The photovoltaic cell of claim 11, wherein the positive and negative interdigitated electrodes comprise molybdenum.

22. The photovoltaic cell of claim 11, wherein the dielectric filler comprises at least one of SiO₂, Al₂O₃, SiN, and mixtures thereof.

23. The photovoltaic cell of claim 11, wherein the substrate comprises at least one of surface-oxidized Ti; a ceramic-coated sheet of Cu, Ni, Al, stainless steel or a Hastelloy; ceramic; and glass-ceramic.

24. The photovoltaic cell of claim 11, further comprising an antireflective layer over the topping layer and comprising at least one of silicon nitride, silicon oxide and titanium oxide.

25. The photovoltaic cell of claim 11, wherein the semiconductor layer comprises one of an n-doped, p-doped, and an intrinsic semiconductor layer.

26. The photovoltaic cell of claim 11, wherein the semiconductor layer has a thickness adapted to maximize absorption of photonic energy.

27. The photovoltaic cell of claim 11, wherein the positive semiconductor strips are p⁺ doped; and wherein the negative semiconductor strips are n⁺ doped.

28. A photovoltaic cell comprising:
a substrate;
positive and negative interdigitated electrode fingers adjacent the substrate;
a dielectric filler between adjacent ones of the interdigitated electrode fingers;
spaced p-type and n-type semiconductor strips on the respective positive and negative interdigitated electrode fingers;
a respective undoped semiconductor strip between adjacent p-type and n-type semiconductor strips;
a semiconductor layer covering the spaced p-type and n-type semiconductor strips and the undoped semiconductor strips; and
a topping layer on the semiconductor layer comprising at least partly crystallized semiconductor having a same conductivity type and a greater dopant concentration than the semiconductor layer.

29. The photovoltaic cell of claim 28, wherein the p-type and n-type semiconductor strips comprise p-type and n-type polysilicon respectively, and wherein the semiconductor layer comprises at least partly crystallized silicon.

30. The photovoltaic cell of claim 28, wherein the positive and negative interdigitated electrode fingers comprise metal.

31. A method of making a photovoltaic cell comprising:
forming positive and negative interdigitated electrode fingers adjacent a substrate;
forming spaced p-type and n-type semiconductor strips on the respective positive and negative interdigitated electrode fingers;
forming a respective undoped semiconductor strip between adjacent p-type and n-type semiconductor strips; and
forming a semiconductor layer covering the spaced p-type and n-type semiconductor strips and the undoped semiconductor strips.

32. The method of claim 31, further comprising disposing a dielectric filler between adjacent ones of the interdigitated electrode fingers.

33. The method of claim 31, wherein the p-type and n-type semiconductor strips comprise p-type and n-type polysilicon respectively, and wherein the semiconductor layer comprises at least partly crystallized silicon.

34. The method of claim 31, wherein the positive and negative interdigitated electrode fingers comprise metal.

35. The method of claim 31, further comprising forming a topping layer on the semiconductor layer comprising at least partly crystallized semiconductor having a same conductivity type and a greater dopant concentration than the semiconductor layer.

36. The method of claim 35, wherein the topping layer has electrical characteristics for recombination of mobile carriers produced by absorption of photonic energy in the semiconductor layer.

37. A method of making a photovoltaic cell comprising:
providing a substrate having a dielectric surface;
depositing a layer of a lithographically etchable metal adapted to establish electrical contact with silicon on the substrate;
patterning a metal layer to define spaced alternately positive and negative electrode fingers of interdigitated electrodes of a two terminal structure, using a first masking and etching of the metal;
filling between adjacent electrode fingers of the patterned metal layer with a dielectric filler;
depositing a layer of hydrogenated amorphous silicon;
defining footprints of the spaced alternately positive and negative electrode fingers by printing layers of a source substance over respective areas of the layer of hydrogenated amorphous silicon;
diffusing the dopants from the print layers of source substance into the hydrogenated amorphous silicon such that hydrogen from the hydrogenated amorphous silicon releases and thereby crystallizes the amorphous silicon to form polysilicon;
removing residues of the printed layers and native oxides from a surface of the polysilicon;
depositing a semiconductor layer of at least partly crystallized; and
increasing dopant concentration the layer of at least partly crystallized silicon and thereby forming an electrically conductive shallow superficial doped diffused region thereon.

38. The method of claim 37, wherein the substrate and the lithographically etchable metal are capable of withstanding temperatures of 700° C. to 1,000° C.

39. The method of claim 37, wherein the layer of hydrogenated amorphous silicon has a thickness between 30 nm and 200 nm; and wherein the semiconductor layer has a thickness of between 200 nm and 100 μm.

40. The method of claim 37, wherein the electrically conductive shallow superficial doped diffused region is one of n⁺ and p⁺ doped.
